(19) United States
(12) Patent Application Publication
(10) Pub. No.: US 2019/0049719 A1
(43) Pub. Date: Feb. 14, 2019

(54) OPTICAL FIBER SCANNER, ILLUMINATION DEVICE, AND OBSERVATION DEVICE

(71) Applicant: OLYMPUS CORPORATION, Tokyo (JP)

(72) Inventors: Hiroshi TSURUTA, Kanagawa (JP); Yasuaki KASAI, Saitama (JP); Hirokazu YOKOTA, Tokyo (JP); Takashi YASUMI, Tokyo (JP)

(73) Assignee: OLYMPUS CORPORATION, Tokyo (JP)

(21) Appl. No.: 16/154,772

(22) Filed: Oct. 9, 2018

Related U.S. Application Data
(63) Continuation of application No. PCT/JP2016/063785, filed on May 9, 2016.

(51) Int. Cl. G02B 26/10; G02B 23/24; H01L 41/09

(52) U.S. Cl. CPC G02B 26/103; H01L 41/0913; G02B 23/2469

(57) ABSTRACT

An optical fiber scanner including: an optical fiber configured to emit, from a distal end thereof, illumination light guided from a light source; and at least three flat-plate-shaped piezoelectric elements that are disposed at positions spaced apart from the distal end that are closer to a proximal end of the optical fiber in the longitudinal axis direction and configured to vibrate the distal end of the optical fiber in a direction intersecting the longitudinal axis, wherein each of the piezoelectric elements has chamfered sections on both widthwise ends along at least a portion thereof in a longitudinal direction, and the piezoelectric elements adjacent in a circumferential direction are assembled into a tubular shape that surrounds the outer circumferential surface of the optical fiber in a close contact manner in a state where the chamfered sections are brought into close contact with one another.

### CROSS-REFERENCE TO RELATED APPLICATIONS

This is a Continuation Application of International Application No. PCT/JP2016/063785 filed on May 9, 2016, the content of which is incorporated herein by reference in its entirety.

### TECHNICAL FIELD

The present invention relates to an optical fiber scanner, an illumination device, and an observation device.

### BACKGROUND ART

There is a known optical fiber scanner that vibrates, by means of a piezoelectric element, a distal end of an optical fiber, which guides light from a light source, in a direction orthogonal to the direction of a longitudinal axis, thereby scanning the light emitted from the distal end (refer to, for example, Patent Literature 1).

The scanning optical system in Patent Literature 1 is formed by affixing, with an adhesive, four flat-plate-shaped piezoelectric elements directly to an outer circumferential surface of an optical fiber. The piezoelectric elements are disposed so as to sandwich the optical fiber therebetween in two directions (x axis and y axis) that are orthogonal to the longitudinal axis (z axis) of the optical fiber and that are orthogonal to each other. The distal end of the optical fiber is vibrated in a spiral shape by periodically changing the amplitudes of, and imparting a phase difference to, alternating voltages applied to the piezoelectric elements arranged in two directions, thus two-dimensionally scanning the emitted light on a subject.

### CITATION LIST

### Patent Literature

{PTL 1}

Japanese Unexamined Patent Application, Publication No. 2014-71423

### SUMMARY OF INVENTION

One aspect of the present disclosure is an optical fiber scanner including: an optical fiber configured to emit, from a distal end thereof, illumination light guided from a light source; and at least three flat-plate-shaped piezoelectric elements that are disposed at positions spaced apart from the distal end that are closer to a proximal end of the optical fiber in a longitudinal axis direction and configured to vibrate the distal end of the optical fiber in a direction intersecting the longitudinal axis, wherein each of the piezoelectric elements has chamfered sections on both widthwise ends thereof along at least a portion thereof in a longitudinal direction, and the piezoelectric elements adjacent in a circumferential direction are assembled into a tubular shape that surrounds an outer circumferential surface of the optical fiber in a close contact manner in a state where the chamfered sections are brought into close contact with one another.

### BRIEF DESCRIPTION OF DRAWINGS

FIG. 1 is a longitudinal sectional view showing an observation device according to one embodiment of the present invention.

FIG. 2 is a perspective view showing one example of a piezoelectric element provided in the observation device in FIG. 1.

FIG. 3 is a perspective view showing an assembly in which four of the piezoelectric elements in FIG. 2 are combined.

FIG. 4 is a front view showing polarization directions of the piezoelectric elements of the assembly in FIG. 3.

FIG. 5 is a front view showing the types of alternating voltages applied to the piezoelectric elements in FIG. 3.

FIG. 6 is a longitudinal sectional view showing a modification of an optical fiber scanner provided in the observation device in FIG. 1.

FIG. 7 is a longitudinal sectional view showing another modification of the optical fiber scanner provided in the observation device in FIG. 1.

FIG. 8 is perspective view showing a modification of the piezoelectric element in FIG. 2.

FIG. 9 is a perspective view showing an assembly in which three of the piezoelectric elements in FIG. 8 are combined.

FIG. 10 is a front view showing polarization directions of the piezoelectric elements of the assembly in FIG. 9.

FIG. 11 is a perspective view showing another modification of the piezoelectric element in FIG. 2.

FIG. 12 is perspective view showing another modification of the piezoelectric element in FIG. 2.

FIG. 13 is a perspective view showing another modification of the piezoelectric element in FIG. 2.

### DESCRIPTION OF EMBODIMENTS

An optical fiber scanner 4, an illumination device 2, and an observation device 1 according to one embodiment of the present invention will now be described with reference to the drawings.

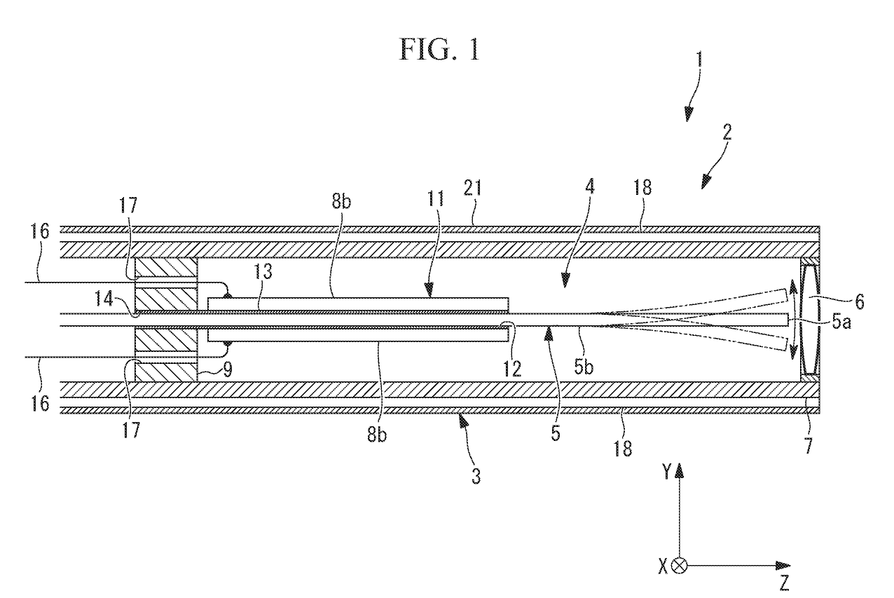

As shown in FIG. 1, the observation device 1 according to this embodiment includes: the illumination device 2 for irradiating a subject with illumination light; and a photodetection unit 3 for detecting return light, such as reflected light and fluorescence returning from the irradiation position of the illumination light on the subject.

The illumination device 2 according to this embodiment includes: a light source (not shown); the optical fiber scanner 4 that two-dimensionally scans illumination light from the light source; a condensing lens 6 for condensing illumination light emitted from a distal end 5a of an optical fiber 5 of the optical fiber scanner 4; and a cylindrical lens holding member 7 that holds the condensing lens 6 at a position further forward from the distal end 5a of the optical fiber 5.

The optical fiber scanner 4 according to this embodiment includes: the optical fiber 5 that guides illumination light from the light source and that emits the illumination light from the distal end 5a; piezoelectric elements 8a and 8b that vibrates the distal end 5a of the optical fiber 5 in directions intersecting the longitudinal axis; and a fixing member 9 that allows the lens holding member 7 to hold the optical fiber 5 at a position closer to the proximal side than the piezoelectric elements 8a and 8b are.

The optical fiber 5 is formed of two types of quartz or plastic materials having refractive indices different from each other: one is a linear core (not shown) and the other is a tubular clad 5b surrounding the periphery of the core.

Each of the piezoelectric elements 8a and 8b is configured by forming film-like electrodes 10 on each of both thickness-wise surfaces of a flat-plate-shaped piezoelectric ceramic material made of lead zirconate titanate.

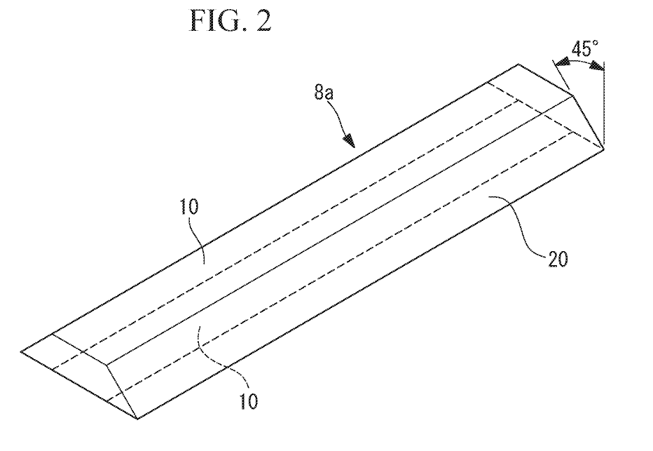

In this embodiment, as shown in FIG. 2, the piezoelectric elements 8a and 8b are each formed to have a trapezoidal shape in transverse section as a result of chamfered sections 20 with an angle of 45° being provided on both widthwise sides thereof along the entire longitudinal length. FIG. 2 shows the piezoelectric element 8a as an example. The electrodes 10 are provided on surfaces corresponding to the upper base and the lower base of the trapezoid and have the same width.

In addition, the optical fiber scanner 4 according to this embodiment includes four piezoelectric elements 8a and 8b. The four piezoelectric elements 8a and 8b have two types of polarization directions, which are set in the thickness direction. In other words, these two types of piezoelectric elements 8a and 8b expand and contract in the longitudinal direction in a manner opposite to each other when a voltage is applied thereto in the same direction.

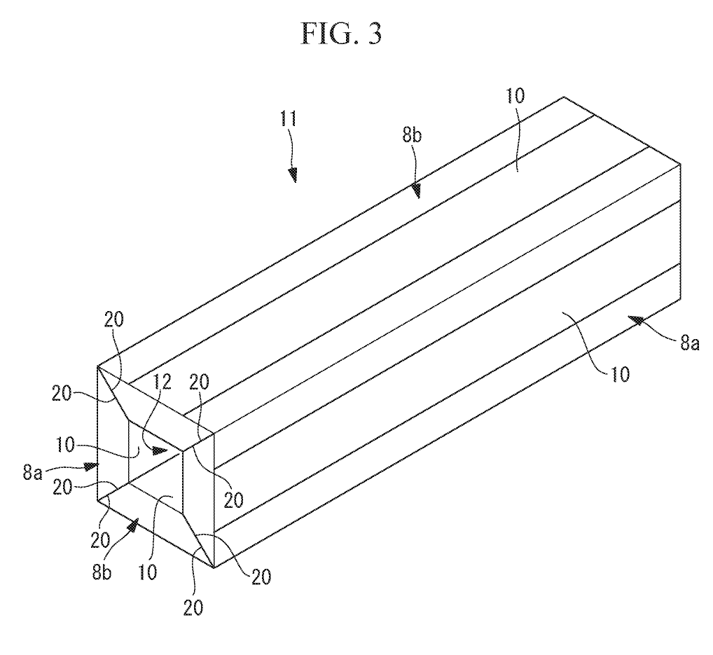

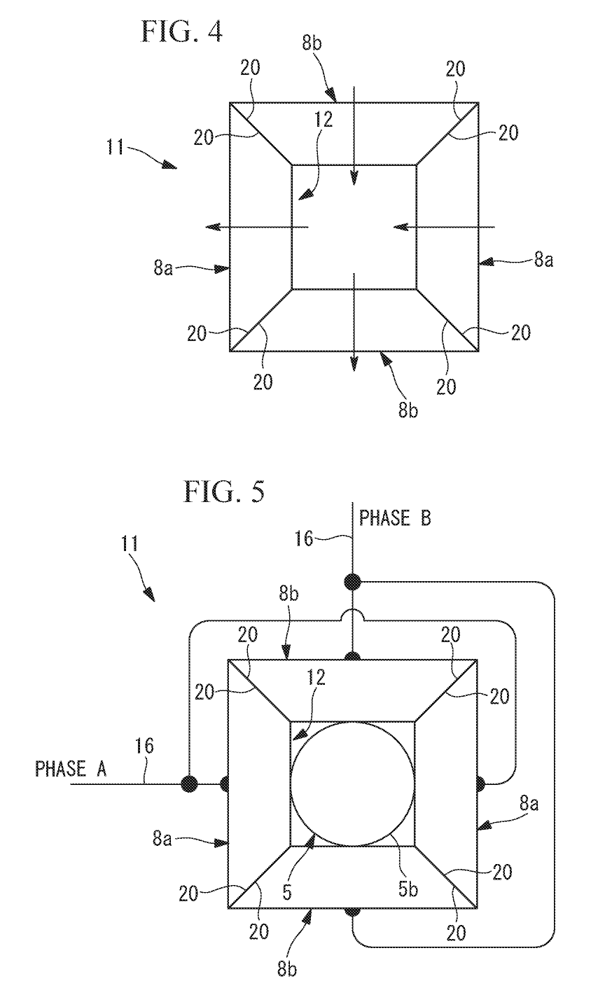

As shown in FIG. 3, the four piezoelectric elements 8a and 8b are assembled into a rectangular-tubular shape by bonding adjacent piezoelectric elements 8a and 8b with an epoxy-based adhesive in a state where the chamfered sections 20 are in close contact with each other. In a rectangular-tubular assembly 11 composed of the piezoelectric elements 8a and 8b, the two piezoelectric elements 8a and 8b that are disposed in parallel with a space therebetween having different polarization directions have been used, as indicated by the arrows in FIG. 4.

A through-hole 12 that is square in transverse section is formed in the rectangular-tubular assembly 11 composed of the piezoelectric elements 8a and 8b so as to pass through the assembly 11 at the center thereof. The length of one side of the transverse section of this through-hole 12 is configured to be substantially equal to the outer diameter of the optical fiber 5. By doing so, the optical fiber 5 can be made to pass through the through-hole 12 of the assembly 11 composed of the piezoelectric elements 8a and 8b and is bonded with a conductive adhesive 13.

The fixing member 9 is a ring-shaped member having a center through-hole 14 through which the optical fiber 5 passes, is formed of a conductive material, and is bonded to the optical fiber 5 with the conductive adhesive (conductive adhesive layer) 13 with which the piezoelectric elements 8a and 8b are bonded to the optical fiber 5. A lead wire (not shown) connected to the ground is connected to the fixing member 9.

Furthermore, the fixing member 9 is provided with through-holes 17 through which lead wires 16 pass, the lead wires 16 being connected to the electrodes 10 provided on the outer side of the assembly 11 composed of the piezoelectric elements 8a and 8b. As described above, the electrodes 10 disposed in the through-hole 12 of the rectangular-tubular assembly 11 composed of the piezoelectric elements 8a and 8b are electrically connect to the fixing member 9 via the conductive adhesive 13 for bonding the electrodes 10 to the optical fiber 5 and thus are all connected to ground.

As shown in FIG. 5, an alternating voltage having phase A is applied to a pair of two piezoelectric elements 8a disposed so as to face each other in the X-axis direction, and an alternating voltage having phase B is applied to a pair of two piezoelectric elements 8b disposed so as to face each other in the Y-axis direction.

The photodetection unit 3 has a plurality of light-receiving optical fibers 18 arranged along the circumferential direction on the outer circumferential surface of the lens holding member 7. The plurality of light-receiving optical fibers 18 are covered with a coating layer 21 and are fixed to the lens holding member 7 in a state where they are arranged along the circumferential direction on the outer circumferential surface of the lens holding member 7. The distal ends of these light-receiving optical fibers 18 are arranged in a state where the front sides thereof are oriented towards the vicinity of the distal end position of the lens holding member 7 so as to receive return light emitted from the subject. The return light received by the distal ends of the light-receiving optical fibers 18 is guided by the light-receiving optical fibers 18, and the total amount of light is detected by a photodetector, not shown in the figure, connected to the proximal end side of the light-receiving optical fibers 18.

The operation of the optical fiber scanner 4, the illumination device 2, and the observation device 1 according to this embodiment with the above-described structure will be described below.

According to the optical fiber scanner 4 of this embodiment, an alternating voltage having phase A is applied to the pair of two piezoelectric elements 8a arranged so as to face each other in the X-axis direction, thereby causing one piezoelectric element 8a to be expanded in the length direction and the other piezoelectric element 8b to be contracted in the length direction. By doing so, the distal end 5a of the optical fiber 5 can be vibrated in the X-axis direction with the vicinity of the axial-direction center of the fixing member 9 serving as a vibration node and with the distal end 5a of the optical fiber 5 serving as a vibration antinode.

Similarly, an alternating voltage having phase B is applied to the pair of two piezoelectric elements 8b arranged so as to face each other in the Y direction, thereby causing one piezoelectric element 8b to be expanded in the length direction and the other piezoelectric element 8a to be contracted in the length direction. By doing so, the distal end 5a of the optical fiber 5 can be vibrated in the Y-axis direction with the vicinity of the axial-direction center of the fixing member 9 serving as a vibration node and with the distal end 5a of the optical fiber 5 serving as a vibration antinode.

The distal end 5a of the optical fiber 5 can be vibrated so as to draw a circular trajectory by producing vibration in the X direction and vibration in the Y direction simultaneously and shifting the phases of the alternating voltages having phase A and phase B by 90°. In this state, the distal end 5a of the optical fiber 5 can be vibrated along a spiral trajectory by periodically changing the amplitudes of the alternating voltages having phase A and phase B.

When illumination light guided by the optical fiber 5 is emitted from the distal end 5a, the emitted illumination light is condensed by the condensing lens 6, which is held in the front by the lens holding member 7, thereby forming a light spot on the subject. As a result of the distal end 5a of the optical fiber 5 being vibrated, the formed light spot is scanned on the subject so as to draw a spiral scanning trajectory.

When the illumination light is scanned on the subject, return light, such as reflection light or fluorescence, generated at each scanning position is received by the light-receiving optical fibers 18 and is detected by the photodetector. Information on the intensity of return light detected by the photodetector is associated with information on the scanning position of the illumination light, thereby generating a return light image of the subject.

In this case, according to the optical fiber scanner 4 of this embodiment, the four piezoelectric elements 8a and 8b are formed into the rectangular-tubular assembly 11 by bonding the four piezoelectric elements 8a and 8b to one another in a state where the chamfered sections 20 of the adjacent piezoelectric elements 8a and 8b are in close contact with each other. Therefore, there is an advantage in that the neighboring piezoelectric elements 8a and 8b can be easily positioned relative to each other.

More specifically, conventionally, in a case where four piezoelectric elements are bonded to an optical fiber, which is circular in transverse section, it was difficult to position the flat-plate-shaped piezoelectric elements relative to the cylindrical surface. According to this embodiment, however, it is easy to position the adjacent piezoelectric elements 8a and 8b relative to each other, thereby making it possible to accurately arrange the two opposed piezoelectric elements 8a in parallel, and also the two opposed piezoelectric elements 8b in parallel.

In general, because a flat-plate-shaped piezoelectric element vibrates in different directions depending on the orientations of the surfaces of the piezoelectric element when the flat-plate-shaped piezoelectric element is disposed, it is necessary to pay sufficient attention concerning the orientation in which the piezoelectric elements are bonded. According to this embodiment, however, the widths of both thickness-wise surfaces of each of the piezoelectric elements 8a and 8b differ from each other due to the chamfered sections 20. Because of this, merely by combining the chamfered sections 20 with each other, all the piezoelectric elements 8a and 8b can be easily arranged with the same surfaces oriented towards the optical fiber 5. As a result, there is an advantage in that each of the piezoelectric elements 8a and 8b can be easily and highly accurately positioned orthogonally to the X axis and Y axis, serving as the two driving axes, thereby making it possible to vibrate the distal end 5a of the optical fiber 5 with a stable vibration trajectory.

Therefore, according to the illumination device 2 of this embodiment, there is an advantage in that the subject can be irradiated uniformly with illumination light emitted from the distal end 5a of the optical fiber 5 that is vibrated with a stable vibration trajectory. According to the observation device 1 of this embodiment, there is another advantage in that the subject can be observed on a return-light image with little distortion on the basis of return light from each of the scanning positions scanned with illumination light of a stable scanning trajectory.

In addition, according to the optical fiber scanner 4 of this embodiment, because a transverse section (cross section taken along a direction orthogonal to the central axis of the optical fiber 5) of the through-hole 12 formed in the rectangular-tubular assembly 11 composed of the piezoelectric elements 8a and 8b is a square, gaps are formed between the inner surfaces of the through-hole 12 and the external surface of the optical fiber 5. For this reason, even if the central axis of the optical fiber 5 is shifted from the central axis of the through-hole 12, it is not necessary to change the direction in which the vibration is transmitted from the piezoelectric elements 8a and 8b to the optical fiber 5. This also affords an advantage in that the vibration state of the optical fiber 5 can be stabilized.

In this embodiment, the four piezoelectric elements 8a and 8b may be assembled into a rectangular-tubular shape, and then the optical fiber 5 may be inserted into the through-hole 12, which is formed in the center and which is rectangular in transverse section, and bonded. Alternatively, two or three piezoelectric elements 8a and 8b may be assembled, then the optical fiber 5 may be disposed along the piezoelectric elements 8a and 8b, and the remaining piezoelectric elements 8a and 8b may be assembled so that the entire outer circumferential surface of the optical fiber 5 is surrounded.

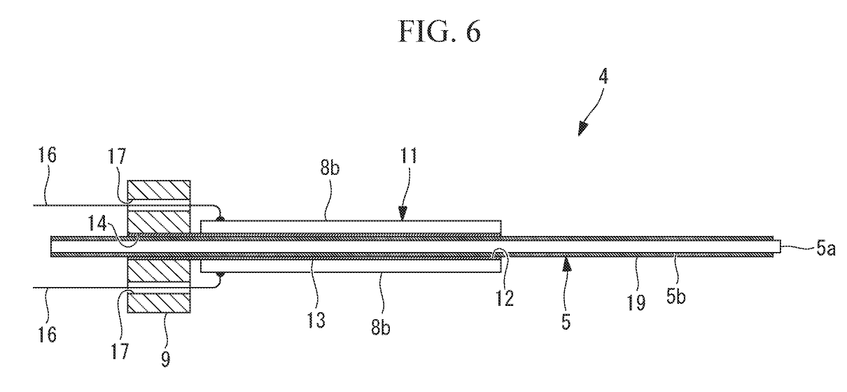

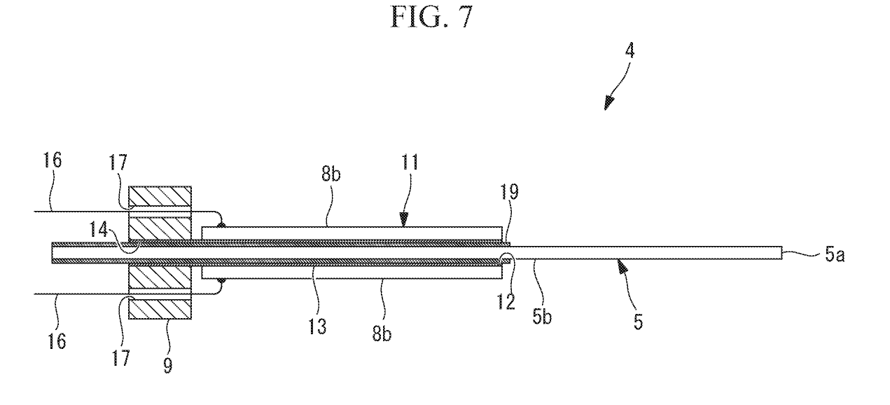

In addition, although this embodiment has been described by way of an example where the optical fiber 5 is provided with the clad 5b and the core, instead of this, an optical fiber 5 having a resin coat (resin layer) 19 covering the outer circumference of the clad 5b may be employed, as shown in FIGS. 6 and 7.

In this case, the resin coat 19 may be arranged up to the vicinity of the distal end 5a of the optical fiber 5, as shown in FIG. 6. Alternatively, the resin coat 19 may be arranged up to the distal end portions of the piezoelectric elements 8a and 8b, as shown in FIG. 7.

The optical fiber 5 has portions that are subjected to stress concentration due to vibration. Providing the resin coat 19 affords an advantage in relaxing this stress concentration and protecting the clad 5b and core of the optical fiber 5 from mechanical damage due to, for example, fatigue.

In addition, in this embodiment, two in-phase piezoelectric elements 8a having different polarization directions and two in-phase piezoelectric elements 8b having different polarization directions are to be used. Both the two in-phase piezoelectric elements 8a and the two in-phase piezoelectric elements 8b are each arranged in parallel to the other of the same phase and in a manner spaced apart from the other, and an equal voltage is applied to the outer side of the rectangular-tubular assembly 11. Instead of this, by applying voltages having anti-phase, all of the piezoelectric elements 8a and 8b may be made common.

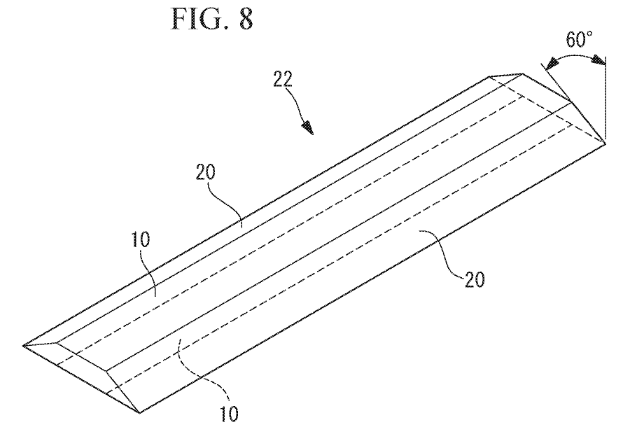

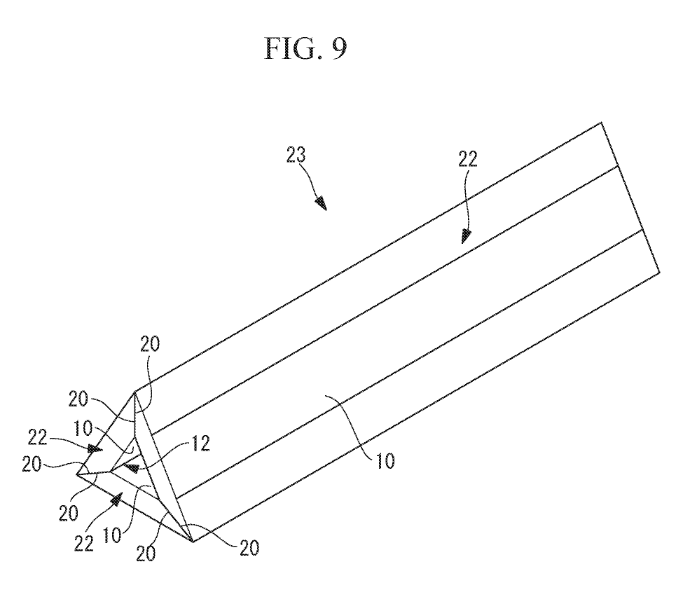

Furthermore, although in this embodiment, the four piezoelectric elements 8a and 8b are assembled into the rectangular-tubular assembly 11, instead of this, three piezoelectric elements 22 having chamfered sections 20 with an angle of 60°, as shown in FIG. 8, may be combined into a triangle-tubular assembly 23, as shown in FIG. 9. In this case, the polarization directions of the piezoelectric elements 22 is set as indicated by the arrows in FIG. 10 and the three-phase alternating voltages having phases shifted by 120° are applied to the piezoelectric elements 22.

In addition, the number of piezoelectric elements 8a, 8b, and 22 is not limited to three or four; rather, any number of piezoelectric elements 8a, 8b, and 22 can be used. If this is the case, the angle θ of a chamfered section 20 is as follows:

θ=360/(number of piezoelectric elements×2)

Regarding the widths of both thickness-wise surfaces of the piezoelectric elements 8a, 8b, and 22 having such chamfered sections 20, because the surface that is to be bonded to the optical fiber 5 is small and the surface on the opposite side from the optical fiber 5 (outer circumferential side of the assembly 11 or the assembly 23) is large, the surfaces to be bonded can be easily recognized at the time of assembly. By doing so, regardless of the number of piezoelectric elements, all the piezoelectric elements 8a, 8b, and 22 can be easily disposed with the same surfaces oriented towards the optical fiber 5, merely by combining the chamfered sections 20 with each other.

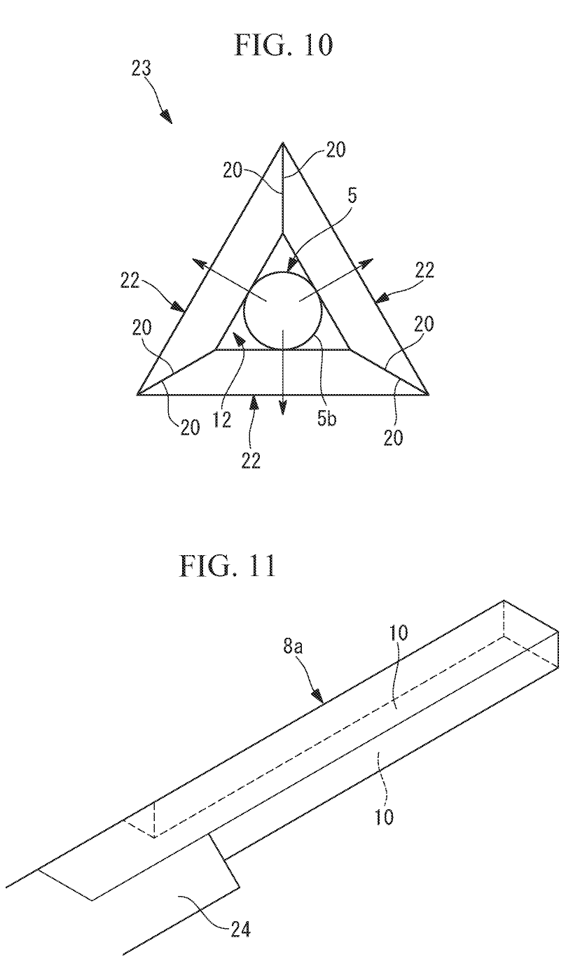

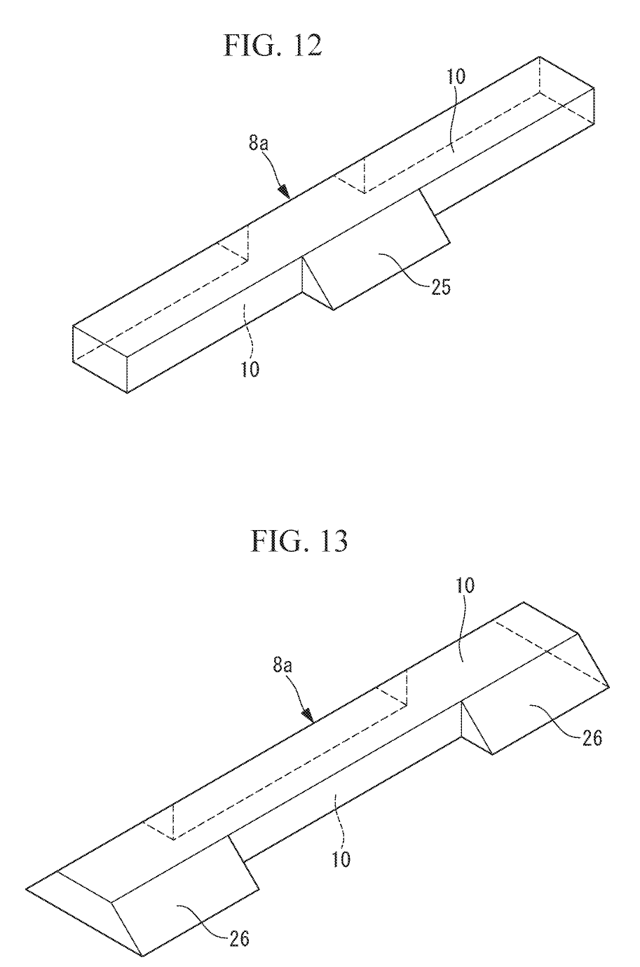

In addition, in this embodiment, the chamfered sections 20 are provided along the entire length in the length direction of the piezoelectric elements 8a and 8b. Instead of this, projections for forming the chamfered sections 24, 25, or 26 may be provided in a part in the length direction, as shown in FIGS. 11 to 13. The chamfered section 24 is provided at one end in the length direction in the example shown in FIG. 11, the chamfered section 25 is provided at the center in the length direction in the example shown in FIG. 12, and the chamfered sections 26 are provided at both ends in the length direction in the example shown in FIG. 13.

From the above-described embodiment, the following aspects of the present disclosure are derived.

One aspect of the present disclosure is an optical fiber scanner including: an optical fiber configured to emit, from a distal end thereof, illumination light guided from a light source; and at least three flat-plate-shaped piezoelectric elements that are disposed at positions spaced apart from the distal end that are closer to a proximal end of the optical fiber in a longitudinal axis direction and configured to vibrate the distal end of the optical fiber in a direction intersecting the longitudinal axis, wherein each of the piezoelectric elements has chamfered sections on both widthwise ends thereof along at least a portion thereof in a longitudinal direction, and the piezoelectric elements adjacent in a circumferential direction are assembled into a tubular shape that surrounds an outer circumferential surface of the optical fiber in a close contact manner in a state where the chamfered sections are brought into close contact with one another.

According to this aspect, the at least three flat-plate-shaped piezoelectric elements are assembled into a tubular shape having a through-hole at the center thereof in a state where the chamfered sections provided on both widthwise ends along at least a portion in the longitudinal direction are brought into close contact with one another, and the optical fiber is made to pass through the through-hole. In this manner, the optical fiber scanner is configured such that the tubular piezoelectric elements surround, in a close contact manner, the midway part of the optical fiber in a longitudinal-direction along the entire circumference. The chamfered sections can be manufactured with high accuracy by machining, and at the time of assembly, relative angles between the plurality of piezoelectric elements can be set with high accuracy. By doing so, the piezoelectric elements can be easily and accurately positioned on the outer circumferential surface of the optical fiber orthogonally to the driving axis thereof, thus achieving a stable vibration trajectory.

The above-described aspect may further include: a fixing member that is fixed to the outer circumferential surface of the optical fiber via a conductive adhesive layer at a position closer to the proximal end than the piezoelectric elements, wherein the fixing member and the piezoelectric elements may be electrically connected via the conductive adhesive layer.

By doing so, the vibration of the optical fiber is supported at a position closer to the proximal end than the piezoelectric elements are by means of the fixing member fixed to the outer circumferential surface of the optical fiber with the conductive adhesive layer therebetween. Furthermore, as a result of the fixing member and the piezoelectric elements being electrically connected via the conductive adhesive layer, it is possible to ground the electrode on the optical fiber side of each of the piezoelectric elements merely by grounding the fixing member.

In addition, in the above-described aspect, the optical fiber may include a resin layer that covers up to a vicinity of the distal end of the optical fiber or up to a distal end side of the piezoelectric elements.

By doing so, the core of the optical fiber is protected by the resin layer, and mechanical fatigue etc. can be reduced.

In addition, in the above-described aspect, the angle of each of the chamfered sections in the piezoelectric elements may be represented by an expression: θ=360/(number of piezoelectric elements×2), where θ is the angle of each of the chamfered sections.

By doing so, in a case where the number of piezoelectric elements is three, the angle θ of each of the chamfered sections is 60°, and when the chamfered sections of adjacent piezoelectric elements are brought into close contact with each other, a regular triangular prism is formed by the three piezoelectric elements, whereby the outer circumferential surface of the optical fiber can be inscribed and fitted in a close contact manner in the through-hole having a regular triangle in transverse section at the center. In addition, in the case where the number of piezoelectric elements is four, the angle θ of each of the chamfered sections is 45°, and when the chamfered sections of adjacent piezoelectric elements are brought into close contact with each other, a square prism is formed by the four piezoelectric elements, whereby the outer circumferential surface of the optical fiber can be inscribed and fitted in a close contact manner in the through-hole having a square in transverse section at the center.

In addition, in the above-described aspect, the widths of electrodes formed on the front and rear surfaces of each of the piezoelectric elements may be the same.

By doing so, a region in which the electrodes face each other can be deformed efficiently.

In addition, another aspect of the present invention is an illumination device including: the above-described optical fiber scanner; a light source configured to generate illumination light that is guided by the optical fiber of the optical fiber scanner; a condensing lens configured to condense illumination light emitted from the distal end of the optical fiber scanner; and a lens holding member that is formed into a tubular shape to accommodate the optical fiber scanner and that is fixed to the fixing member, the lens holding member configured to support the condensing lens at a position further forward from the distal end of the optical fiber scanner.

According to this aspect, illumination light from the light source is guided by the optical fiber, and illumination light emitted from the distal end of the vibrating optical fiber is condensed by the condensing lens into a light spot, which is radiated on the subject. By fixing the tubular lens holding member that holds the condensing lens and the fixing member, the optical fiber scanner is reliably held by the lens holding member at a position closer to the proximal side than the piezoelectric elements are, allowing the light spot to be scanned with a stable scanning trajectory and the subject to be irradiated uniformly.

In addition, still another aspect of the present invention is an observation device including: the above-described illumination device; and a photodetection unit configured to detect return light returning from a subject as a result of illumination light being irradiated by the illumination device.

According to this aspect, as a result of the light spot being scanned by the illumination device, return light returning from a scanning position of the subject is detected by the photodetion unit and is associated with the scanning position, thereby allowing a return light image of the subject to be acquired. By scanning the light spot with a stable scanning trajectory, the subject can be observed on a return light image with little distortion.

According to the aforementioned aspects, there is an advantage in that piezoelectric elements can be easily and highly accurately positioned on the outer circumferential surface of an optical fiber such that the piezoelectric elements are orthogonal to the driving axis of the optical fiber, thereby achieving a stable vibration trajectory.

### REFERENCE SIGNS LIST

1 Observation device
2 Illumination device
3 Photodetection unit
4 Optical fiber scanner
5 Optical fiber
5a Distal end
6 Condensing lens
7 Lens holding member
8a, 8b, 22 Piezoelectric element
9 Fixing member
10 Electrode
13 Adhesive (conductive adhesive layer)
19 Resin coat (resin layer)
20, 24, 25, 26 Chamfered section

1. An optical fiber scanner comprising:
an optical fiber configured to emit, from a distal end thereof, illumination light guided from a light source; and
at least three flat-plate-shaped piezoelectric elements that are disposed at positions spaced apart from the distal end that are closer to a proximal end of the optical fiber in a longitudinal axis direction and configured to vibrate the distal end of the optical fiber in a direction intersecting the longitudinal axis,
wherein each of the piezoelectric elements has chamfered sections on both widthwise ends thereof along at least a portion thereof in a longitudinal direction, and
the piezoelectric elements adjacent in a circumferential direction are assembled into a tubular shape that surrounds an outer circumferential surface of the optical fiber in a close contact manner in a state where the chamfered sections are brought into close contact with one another.

2. The optical fiber scanner according to claim 1, further comprising:
a fixing member that is fixed to the outer circumferential surface of the optical fiber via a conductive adhesive layer at a position closer to the proximal end than the piezoelectric elements,
wherein the fixing member and the piezoelectric elements are electrically connected via the conductive adhesive layer.

3. The optical fiber scanner according to claim 1, wherein the optical fiber includes a resin layer that covers up to a vicinity of the distal end of the optical fiber or up to a distal end side of the piezoelectric elements.

4. The optical fiber scanner according to claim 1, wherein the angle of each of the chamfered sections in the piezoelectric elements is represented by an expression:
θ=360/(number of piezoelectric elements×2),
where θ is the angle of each of the chamfered sections.

5. The optical fiber scanner according to claim 1, wherein the widths of electrodes formed on the front and rear surfaces of each of the piezoelectric elements are the same.

6. An illumination device comprising:
the optical fiber scanner according to claim 2;
a light source configured to generate illumination light that is guided by the optical fiber of the optical fiber scanner;
a condensing lens configured to condense illumination light emitted from the distal end of the optical fiber scanner; and
a lens holding member that is formed into a tubular shape to accommodate the optical fiber scanner and that is fixed to the fixing member, the lens holding member configured to support the condensing lens at a position further forward from the distal end of the optical fiber scanner.

7. An observation device comprising:
the illumination device according to claim 6; and
a photodetection unit configured to detect return light returning from a subject as a result of illumination light being irradiated by the illumination device.
